(19) United States
(12) Patent Application Publication
(10) Pub. No.: US 2024/0292689 A1
(43) Pub. Date: Aug. 29, 2024

(54) DISPLAY DEVICE AND DISPLAY PANEL

(71) Applicant: LG Display Co., Ltd., Seoul (KR)

(72) Inventors: Soonsung AHN, Paju-si (KR); SeHwan NA, Paju-si (KR); Taehwi KIM, Paju-si (KR); JinHo LIM, Paju-si (KR); Jaesung KIM, Paju-si (KR)

(73) Assignee: LG Display Co., Ltd., Seoul (KR)

(21) Appl. No.: 18/441,834

(22) Filed: Feb. 14, 2024

(30) Foreign Application Priority Data
Feb. 23, 2023 (KR) 10-2023-0024615

(51) Int. Cl. H10K 59/131; H10K 59/121

(52) U.S. Cl. CPC H10K 59/131; H10K 59/1213

(57) ABSTRACT

A display device and a display panel are discussed. In one example, the display device includes a data driving circuit to supply a plurality of data voltages to a plurality of data lines, wherein the plurality of data lines comprise first data lines and second data lines; a gate driving circuit to supply a plurality of gate signals to a plurality of gate lines; and a display panel having the first data lines disposed in a first area corresponding to the data driving circuit, and the second data lines disposed in a second area located outside of the first area. Further, the display panel can include first data link lines for connecting the first data lines to the data driving circuit, and second data link lines with connecting paths arranged in a stepped line configuration for connecting the second data lines to the data driving circuit.

### CROSS REFERENCE TO RELATED APPLICATION

This application claims priority to Korean Patent Application No. 10-2023-0024615, filed in the Republic of Korea on Feb. 23, 2023, the entire contents of which is hereby expressly incorporated by reference into the present application.

### BACKGROUND

### Field

Embodiments of the present disclosure relate to a display panel and a display device including the same, and, more particularly, to a display panel and a display device including the same that are capable of implementing a lightweight narrow bezel and improving image quality by reducing the coupling capacitance associated with data link lines disposed in the display area of the display panel.

### Discussion of Related Art

In response to the development of the information society, a variety of demands for image display devices are increasing. In this regard, a range of display devices, such as liquid crystal display (LCD) devices and organic light emitting display devices, have come into widespread use and provide various advantageous features.

Among such display devices, organic light emitting display devices including organic light emitting diodes are advantageous in terms of rapid response rate, high contrast ratio, high emission efficiency, high luminance, wide viewing angle, and the like, since the organic light emitting diodes for emitting light by themselves are used therein.

Particularly, the organic light emitting display device can include organic light emitting diodes (OLEDs) disposed in a plurality of subpixels arrayed in a display panel, and can control the OLEDs to emit light by controlling current flowing through the OLEDs, thereby displaying an image while controlling the luminance of the subpixels. The display panel can include a display area for displaying an image and a bezel area formed outside of the display area.

In such display devices, research into minimizing the width of the bezel area formed outside of the display area has been being actively undertaken in order to reduce the overall weight and size of the display device and to make the appearance of the display device more aesthetically appealing.

### BRIEF SUMMARY OF THE DISCLOSURE

In this regard, the inventors of the present disclosure have a display panel and a display device including the same that are capable of implementing a lightweight narrow bezel and improving image quality.

Embodiments of the present disclosure can a display panel and a display device including the same that are capable of implementing a lightweight narrow bezel and improving image quality by reducing the coupling capacitance associated with data link lines disposed in the display area of the display panel.

Embodiments of the present disclosure can provide a display panel and a display device including the same that are capable of implementing a narrow bezel and improving image quality by forming a part of data link lines located in a display area of the display panel in stepped line structures.

Embodiments of the present disclosure can provide a display panel and a display device including the same, which address the limitations and disadvantages associated with the related art.

Embodiments of the present disclosure can provide a display device including a data driving circuit configured to supply a plurality of data voltages to a plurality of data lines, a gate driving circuit configured to supply a plurality of gate signals to a plurality of gate lines, a display panel having a plurality of first data lines disposed in a first area corresponding to the data driving circuit, wherein the plurality of data lines comprises the plurality of first data lines and the plurality of second data lines, and a plurality of second data lines disposed in a second area located outside of the first area, a timing controller configured to control the data driving circuit and the gate driving circuit, wherein the display panel includes a plurality of first data link lines for connecting the plurality of the first data lines to the data driving circuit, and a plurality of second data link lines with connection paths of a stepped line structure for connecting the plurality of second data lines to the data driving circuit.

Embodiments of the present disclosure can provide a display panel including a plurality of subpixels, a plurality of first data lines disposed in a first area corresponding to a data driving circuit, a plurality of second data lines disposed in a second area located outside of the first area, a plurality of gate lines, a plurality of first data link lines for connecting the first data lines to the data driving circuit, and a plurality of second data link lines with connecting paths of a stepped line structure for connecting the plurality of second data lines to the data driving circuit.

Embodiments of the present disclosure can provide a display panel including a substrate, a first buffer layer disposed on the substrate, a driving transistor disposed on the first buffer layer, a first interlayer insulating film disposed on the driving transistor, a second buffer layer disposed on the first interlayer insulating film, at least one switching transistor disposed on the second buffer layer, a second interlayer insulating film formed to cover the at least one switching transistor, a plurality of (2-3)th data link lines disposed on the second interlayer insulating film, a first planarization layer formed to cover the plurality of (2-3)th data link lines, a plurality of data lines and a plurality of (2-2)th data link lines disposed on the first planarization layer, a second planarization layer formed to cover the plurality of data lines and the plurality of (2-2)th data link lines on the first planarization layer, and a light emitting element disposed on the second planarization layer, wherein the plurality of (2-2)th data link lines are connected to a plurality of (2-1)th data link lines extending from the data driving circuit, and wherein the plurality of data lines and the plurality of (2-2)th data link lines are connected to the plurality of (2-3)th data link lines through contact holes.

According to embodiments of the present disclosure, the display device and the display panel can implement a lightweight narrow bezel (bezel area) and improve the image quality.

According to embodiments of the present disclosure, the display device and the display panel can implement a lightweight narrow bezel (bezel area) and improve image quality by reducing the coupling capacitance due to data link lines disposed in the display area of the display panel.

According to embodiments of the present disclosure, the display device and the display panel can implement a lightweight narrow bezel and improve image quality by forming the data link lines located in the display area of the display panel in stepped line structures.

Additional features, advantages, and aspects of the present disclosure are set forth in part in the present disclosure and will also be apparent from the present disclosure or can be learned by practice of the inventive concepts provided herein. Other features, advantages, and aspects of the present disclosure can be realized and attained by the structure particularly pointed out in the present disclosure, or derivable therefrom, and claims hereof as well as the appended drawings.

### BRIEF DESCRIPTION OF THE DRAWINGS

The above and other objectives, features, and advantages of the present disclosure will be more clearly understood from the following detailed description, taken in conjunction with the accompanying drawings, in which:

FIG. 1 is a diagram schematically illustrating a display device according to embodiments of the present disclosure;

FIG. 2 is an example diagram illustrating a system of the display device according to embodiments of the present disclosure;

FIG. 3 is a diagram illustrating an example of a subpixel circuit in the display device according to embodiments of the present disclosure;

FIG. 4 is a plan diagram illustrating a display panel according to a related art;

FIG. 5 is an enlarged diagram of the part A in FIG. 4;

FIG. 6 is a diagram showing an example of a plurality of data lines based on locations in a display device according to embodiments of the present disclosure;

FIG. 7 is a diagram illustrating a connecting structure of data lines disposed in a first area corresponding to a data driving circuit in the display device according to embodiments of the present disclosure;

FIG. 8 is a diagram separately illustrating a connecting structure of a plurality of second data lines disposed in a second areas located outside of the first area in the display device according to embodiments of the present disclosure;

FIG. 9 is a plan view illustrating the structure of a display panel according to embodiments of the present disclosure;

FIG. 10 is a plan view showing a portion of data lines and data link lines in a display panel according to embodiments of the present disclosure;

FIG. 11 is a cross-sectional view showing area B of FIG. 10;

FIG. 12 is a diagram illustrating a case in which a stain is formed in an area due to the data link lines with straight line structure in a row direction;

FIG. 13 is a circuit diagram illustrating a phenomenon in which coupling capacitance is formed due to the (2-3)th data link lines with a straight line structure in a row direction in the display area of the display panel of FIG. 12;

FIG. 14 is an experimental diagram illustrating a variation of driving current flowing in subpixels in a column direction when the (2-3)th data link lines in a row direction are formed in a straight line structure in the display area of the display panel of FIG. 12;

FIG. 15 is a diagram illustrating a plan view of a subpixel with the plurality of second data link lines with a stepped line structure in a display device according to embodiments of the present disclosure;

FIG. 16 is a circuit diagram illustrating a phenomenon in which coupling capacitance is formed due to the (2-3)th data link lines with connection paths of a stepped line structure in the display area of the display panel of the present disclosure;

FIG. 17 is an experimental diagram illustrating a variation of driving current flowing in subpixels when the (2-3)th data link lines with connecting paths in a stepped line structure are connected to the (2-2)th data link lines DLLG2-2 in the display area of the display panel of the present disclosure;

FIG. 18 is a diagram illustrating stains according to shapes of the (2-3)th data link lines in a display device according to a comparison example and an example of the present disclosure; and

FIG. 19 is a plan view illustrating a structure of a display panel having the (2-3)th data link lines of different arrangement structures in a display device according to embodiments of the present disclosure.

### DETAILED DESCRIPTION OF THE EMBODIMENTS

Hereinafter, various embodiments and examples of the present disclosure will be described in detail with reference to exemplary drawings. In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear.

Embodiments are example embodiments. Aspects are example aspects. Any implementation described herein as an “example” is not necessarily to be construed as preferred or advantageous over other implementations.

The terms such as “including”, “having”, “containing”, “constituting”, “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can”.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship. In one or more aspects, the components of each device, panel, apparatus and other entity according to various embodiments of the present disclosure are operatively coupled and configured.

Hereinafter, various embodiments of the present disclosure will be described in detail with reference to the accompanying drawings.

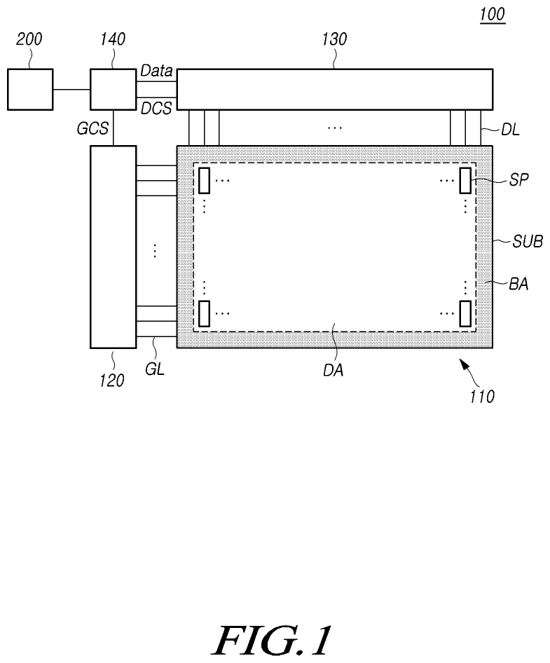

FIG. 1 is a diagram schematically illustrating a display device according to embodiments of the present disclosure.

Referring to FIG. 1, a display device 100 according to the embodiments of the present disclosure can include a display panel 110 and a driving circuit for driving the display panel 110.

The display panel 110 can include a display area DA on which images are displayed and a bezel area BA on which no images are displayed. The bezel area BA can also be referred to as a non-display area.

The display panel 110 can include a plurality of subpixels SP to display images. For example, the plurality of subpixels SP can be disposed in the display area DA. The plurality of subpixels SP in the display area DA can be disposed in a matrix configuration and other arrangements. In some cases, at least one subpixel SP can be disposed in the bezel area BA. The at least one subpixel SP disposed in the bezel area BA is referred to as a dummy subpixel.

The display panel 110 can include a plurality of signal lines to drive the plurality of subpixels SP. For example, the plurality of signal lines can include a plurality of data lines DL and a plurality of gate lines GL, which can be disposed perpendicular to each other or in other configurations. The signal lines can further include additional signal lines other than the plurality of data lines DL and the plurality of gate lines GL according to the structure of the subpixels SP. For example, the additional signal lines can include driving voltage lines, reference voltage lines, and the like.

The plurality of data lines DL can intersect the plurality of gate lines GL. Each of the plurality of data lines DL can be disposed to extend in a first direction. Each of the plurality of gate lines GL can be disposed to extend in a second direction. Here, the first direction can be a column direction, while the second direction can be a row direction. In this specification, the column direction and the row direction are relative terms. In an example, the column direction can be a vertical direction, while the row direction can be a horizontal direction. In another example, the column direction can be a horizontal direction, while the row direction can be a vertical direction. In an example, the first and second directions can be perpendicular to each other.

The driving circuit can include a data driving circuit 130 to drive the plurality of data lines DL and a gate driving circuit 120 to drive the plurality of gate lines GL. The driving circuit can further include a timing controller 140 to control the data driving circuit 130 and the gate driving circuit 120.

The data driving circuit 130 is a circuit to drive the plurality of data lines DL, and can output data signals (also referred to as data voltages) corresponding to an image signal to the plurality of data lines DL. The gate driving circuit 120 is a circuit to drive the plurality of gate lines GL, and can generate and output gate signals to the plurality of gate lines GL. The gate signals can include one or more scan signals and an emission signal.

The timing controller 140 can start scanning in timing set for respective frames and control data driving at appropriate points in time in response to the scanning. The timing controller 140 can convert image data input from an external source into image data Data having a data signal format readable by the data driving circuit 130 and output the image data Data to the data driving circuit 130.

The timing controller 140 can receive display drive control signals together with the input image data from a host system 200. For example, the display drive control signals can include a vertical synchronization signal, a horizontal synchronization signal, an input data enable signal, a clock signal, and the like.

The timing controller 140 can generate a data drive control signal DCS and a gate drive control signal GCS on the basis of the display drive control signals input from the host system 200. The timing controller 140 can control the drive operation and the drive timing of the data driving circuit 130 by supplying the data drive control signal DCS to the data driving circuit 130. The timing controller 140 can control the drive operation and the drive timing of the gate driving circuit 120 by supplying the gate drive control signal GCS to the gate driving circuit 120.

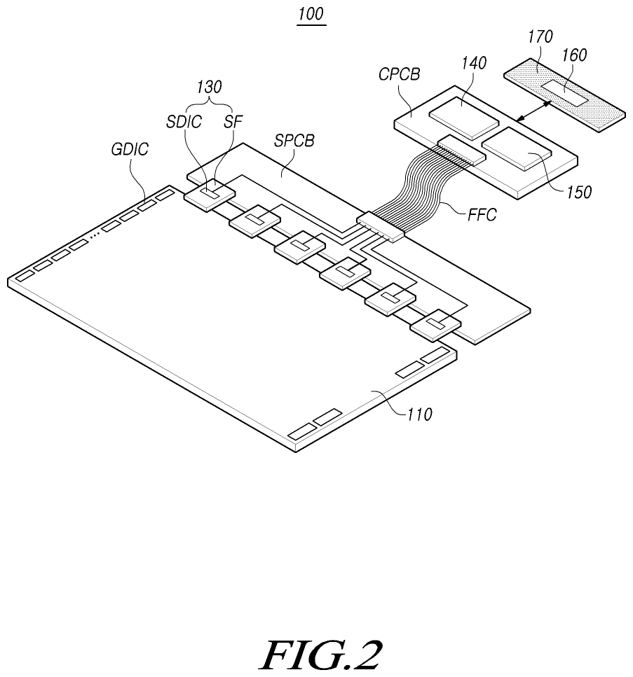

The data driving circuit 130 can include one or more source driving integrated circuits SDIC (e.g., see FIG. 2). Each of the source driving integrated circuits SDIC can include a shift register, a latch circuit, a digital-to-analog converter (DAC), an output buffer, and the like. Each of the source driving integrated circuits SDIC can further include an analog-to-digital converter (ADC).

For example, each of the source driving integrated circuits SDIC can be connected to the display panel 110 using a tape-automated bonding (TAB) structure, can be connected to a bonding pad of the display panel 110 using a chip-on-glass (COG) structure or a chip-on-panel COP structure, or can be implemented using a chip-on-film (COF) structure connected to the display panel 110.

The gate driving circuit 120 can output a gate signal having a turn-on-level voltage or a gate signal having a turn-off-level voltage under the control of the timing controller 140. The gate driving circuit 120 can sequentially drive the plurality of gate lines GL by sequentially supplying the gate signal having a turn-on-level voltage to the plurality of gate lines GL.

The gate driving circuit 120 can include one or more gate driving integrated circuits GDIC (see FIG. 2).

The gate driving circuit 120 can be connected to the display panel 110 using a TAB structure, connected to bonding pads of the display panel 110 using a COG structure or a COP structure, or connected to the display panel 110 using a COF structure. Alternatively, the gate driving circuit 120 can be implemented using a gate-in-panel (GIP) structure provided in the bezel area BA of the display panel 110. The gate driving circuit 120 can be disposed on a circuit board or connected to the circuit board. For example, when the gate driving circuit 120 has a GIP structure, the gate driving circuit 120 can be disposed in the bezel area BA. When the gate driving circuit 120 has a COG structure, a COF structure, or the like, the gate driving circuit 120 can be connected to the circuit board.

In addition, at least one driving circuit of the data driving circuit 130 and the gate driving circuit 120 can be disposed in the display area DA. For example, at least one driving circuit of the data driving circuit 130 and the gate driving circuit 120 can be disposed to not overlap the subpixels SP or disposed such that a portion or the entirety thereof overlaps the subpixels SP.

The data drive data driving circuit 130 can be connected to one side (e.g., the upper side or the lower side) of the display panel 110. The data drive data driving circuit 130 can be connected to both sides (e.g., the upper side and the lower side) of the display panel 110 or two or more sides of four sides of the display panel 110, depending on the driving method, the design of the display panel, or the like.

The gate driving circuit 120 can be connected to one side (e.g., the left side or the right side) of the display panel 110. The gate driving circuit 120 can be connected to both sides (e.g., the left side and the right side) of the display panel 110 or two or more sides of four sides of the display panel 110, depending on the driving method, the design of the display panel, or the like.

The timing controller 140 can be provided as a component separate from the data driving circuit 130 or can be combined with the data driving circuit 130 to form an integrated circuit (IC). The timing controller 140 can be a timing controller used in typical display technology, can be a control device including a timing controller and performing other control functions, or can be a circuit in the control device. The timing controller 140 can be implemented as any of a variety of circuits or electronic components such as an IC, a field programmable gate array (FPGA), an application specific integrated circuit (ASIC), or a processor.

The timing controller 140 can be mounted on a printed circuit board (PCB), a flexible printed circuit (FPC), or the like, and can be electrically connected to the data driving circuit 130 and the gate driving circuit 120 through the PCB, the FPC, or the like. The timing controller 140 can transmit and receive signals to and from the data driving circuit 130 according to predetermined one or more interfaces. Here, for example, the interfaces can include a low voltage differential signaling (LVDS) interface, an embedded panel interface (EPI), a serial peripheral (SP) interface, and the like.

The display device 100 according to embodiments of the present disclosure can be a self-light emitting display device in which the display panel 110 emits light by itself. When the display device 100 according to embodiments of the present disclosure is a self-light emitting display device, each of the plurality of subpixels SP can include a light emitting element. In an example, the display device 100 according to embodiments of the present disclosure can be an organic light emitting display device in which light emitting elements are organic light emitting diodes (OLEDs). In another example, the display device 100 according to embodiments of the present disclosure can be an inorganic light emitting display device in which light emitting elements are light emitting diodes (LEDs) based on an inorganic material. In another example, the display device 100 according to embodiments of the present disclosure can be a quantum dot display device in which light emitting elements are quantum dots serving as self-light emitting semiconductor crystals.

FIG. 2 is an example diagram illustrating a system of the display device according to embodiments of the present disclosure.

Referring to FIG. 2, the display device 100 according to the embodiments of the present disclosure is an example in which the data driving circuit 130 is implemented using a COF structure from among a variety of structures such as TAB, COG, and COF structures, and the gate driving circuit 120 is implemented using a GIP structure from among a variety of structures such as TAB, COG, COF, and GIP structures.

When the gate driving circuit 120 has the GIP structure, the plurality of gate driving integrated circuits GDIC of the gate driving circuit 120 can be directly formed in the bezel area of the display panel 110. Here, the gate driving integrated circuits GDIC can be provided with a variety of signals (e.g., a clock, a gate high signal, and a gate low signal) required for generation of scan signals through gate driving-related signal lines disposed in the bezel area.

In the same manner, the source driving integrated circuits SDIC of the data driving circuit 130 can be mounted on source films SF, respectively. One side of each of the source films SF can be electrically connected to the display panel 110. In addition, conductive lines electrically connecting the source driving integrated circuits SDIC to the display panel 110 can be disposed on the top portions of the source films SF.

The display device 100 can include at least one source printed circuit board SPCB and a control printed circuit board CPCB for circuit connection of the plurality of source driving integrated circuits SDIC to other devices. Here, control components and a variety of electrical devices can be mounted on the control printed circuit board CPCB.

Here, the other sides of the source films SF on which the source driving integrated circuits SDIC are mounted can be connected to the source printed circuit board SPCB. For example, each of the source films SF on which the source driving integrated circuits SDIC are mounted can be configured such that one side thereof is electrically connected to the display panel 110 and the other side thereof is electrically connected to the source printed circuit board SPCB.

The timing controller 140 and a power management circuit 150 can be mounted on the control printed circuit board CPCB. The timing controller 140 can control the operation of the data driving circuit 130 and the gate driving circuit 120. The power management circuit 150 can supply a driving voltage or current to the display panel 110, the data driving circuit 130, the gate driving circuit 120, and the like and can control the supplied voltage or current.

The source printed circuit board SPCB and the control printed circuit board CPCB can be circuit-connected to each other through at least one connecting member. The connecting member can be, for example, a flexible flat cable FFC, a flexible printed circuit (FPC), or the like. In addition, the source printed circuit board SPCB and the control printed circuit board CPCB can be integrated into a single printed circuit board (PCB).

The display device 100 can further include a set board 170 electrically connected to the control printed circuit board CPCB. Here, the set board 170 can also be referred to as a power board. The set board 170 can be provided with a main power management circuit 160 to manage the overall power of the display device 100. The main power management circuit 160 can work in concert with the power management circuit 150.

In the display device 100 having the above-described configuration, a driving voltage is generated by the set board 170 and is transferred to the power management circuit 150 in the control printed circuit board CPCB. The power management circuit 150 transfers the driving voltage, needed for display driving or characteristic value sensing, to the source printed circuit board SPCB through the flexible printed circuit or the flexible flat cable FFC. The driving voltage transferred to the source printed circuit board SPCB is supplied through the driving integrated circuits SDIC in order to light or sense a specific subpixel SP in the display panel 110.

Here, each of the subpixels SP arrayed in the display panel 110 of the display device 100 can include a light emitting element and circuit elements, such as a driving transistor, for driving the light emitting element.

The type and number of the circuit elements provided in each of the subpixels SP can differ and be determined variously depending on functions to be provided, designs, and the like.

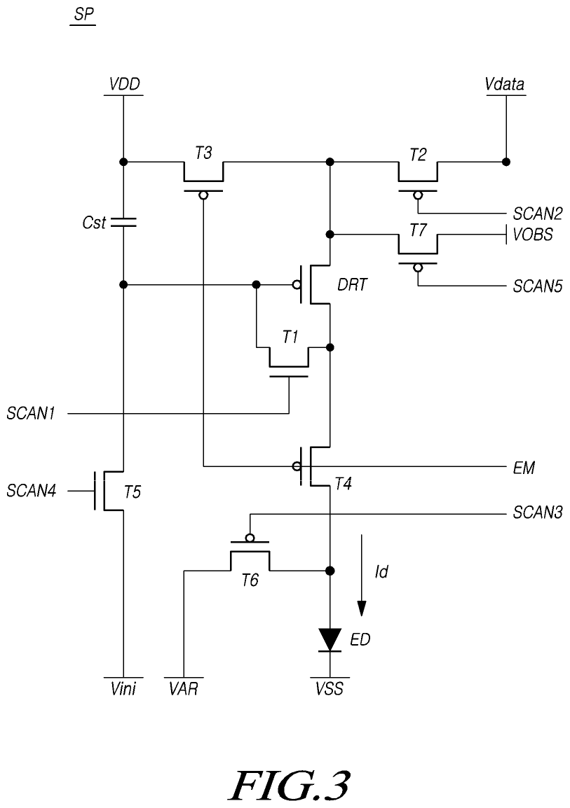

FIG. 3 is a diagram illustrating a subpixel circuit in the display device according to embodiments of the present disclosure.

Referring to FIG. 3, a subpixel SP in the display device 100 according to embodiments of the present disclosure can include first to seventh switching transistors T1 to T7, a driving transistor DRT, a storage capacitor Cst, and a light emitting element ED. As an example, each subpixel SP of the display device 100 of FIGS. 1 and 2 can have the subpixel configuration of FIG. 3.

Here, the light emitting element ED can be, for example, a self-light emitting element, such as an organic light emitting diode (OLED), able to emit light by itself.

In the subpixel SP according to some embodiments of the present disclosure, the second to fourth switching transistors T2 to T4, the sixth switching transistor T6, the seventh switching transistor T7, and the driving transistor DRT can be P-type transistors, while the first switching transistor T1 and the fifth switching transistor T5 can be N-type transistors.

Here, P-type transistors can be more reliable than N-type transistors. P-type transistors have an advantage in that current flowing through the light emitting element ED is not fluctuated by the capacitor Cst, since the source electrode can be fixed to a high-potential driving voltage VDD during lighting. Thus, it is easy to reliably supply current.

For example, when a P-type transistor is connected to the anode of the light emitting element ED and operates in a saturation region, a predetermined amount of current can be flown irrespective of changes in the threshold voltage. Thus, relatively high reliability can be achieved using the P-type transistor.

In this structure of the subpixel SP, each of the N-type transistors T1 and T5 can be formed of an oxide transistor (e.g., a transistor having a channel formed from an oxide semiconductor such as an In, Ga, or Zn oxide or an indium gallium zinc oxide (IGZO)) formed using a semiconducting oxide, while each of the P-type transistors DRT, T2 to T4, T6, and T7 can be a silicon (Si) transistor (e.g., a transistor referred to as a low-temperature polycrystalline silicon (LTPS) transistor having a poly-Si channel formed using a low-temperature process) formed from a transistor material such as Si.

The oxide transistor has a lower leakage current than the silicon transistor. Thus, when a transistor is formed of an oxide transistor, a leakage current from the gate electrode of the driving transistor DRT can be prevented, thereby reducing defects in image quality such as flickers.

In addition, each of the P-type transistors DRT, T2 to T4, T6, and T7, except for the N-type transistors such as the first switching transistor T1 and the fifth switching transistor T5, can be formed of an LTPS transistor.

The source electrode and the drain electrode of each of the switching transistors can be switched and referred to as a drain electrode and a source electrode depending on the input voltage.

The gate electrode of the first switching transistor T1 is provided with a first scan signal SCAN1. The drain electrode of the first switching transistor T1 is connected to the gate electrode of the driving transistor DRT. In addition, the source electrode of the first switching transistor T1 is connected to the drain electrode of the driving transistor DRT.

The first switching transistor T1 is turned on by the first scan signal SCAN1 to maintain the gate voltage of the driving transistor DRT constant using the storage capacitor Cst, one terminal of which is fixed to the high-potential driving voltage VDD.

The first switching transistor T1 can be formed of an N-type MOS transistor to form an oxide transistor. Since N-type MOS transistors use electrons as carriers instead of holes, N-type MOS transistors can have higher mobility and thus higher switching speeds than P-type MOS transistors.

The gate electrode of the second switching transistor T2 is provided with a second scan signal SCAN2. The source electrode of the second switching transistor T2 can be provided with a data voltage Vdata. The drain electrode of the second switching transistor T2 is connected to the source electrode of the driving transistor DRT.

The second switching transistor T2 is turned on by the second scan signal SCAN2 to supply the data voltage Vdata to the source electrode of the driving transistor DRT.

The gate electrode of the third switching transistor T3 is provided with an emission signal EM. The source electrode of the third switching transistor T3 is provided with the high-potential driving voltage VDD. The drain electrode of the third switching transistor T3 is connected to the source electrode of the driving transistor DRT.

The third switching transistor T3 is turned on by the emission signal EM to supply the high-potential driving voltage VDD to the source electrode of the driving transistor DRT.

The gate electrode of the fourth switching transistor T4 is provided with the emission signal EM. The source electrode of the fourth switching transistor T4 is connected to the drain electrode of the driving transistor DRT. The drain electrode of the fourth switching transistor T4 is connected to the anode of the light emitting element ED.

The fourth switching transistor T4 is turned on by the emission signal EM to supply a driving current Id to the anode of the light emitting element ED.

The gate electrode of the fifth switching transistor T5 is provided with a fourth scan signal SCAN4.

Here, the fourth scan signal SCAN4 can be a signal having a different phase from the first scan signal SCAN1 supplied to a subpixel SP in another position. For example, when the first scan signal SCAN1 is applied to the nth gate line, the fourth scan signal SCAN4 can be a first scan signal SCAN1[n−1] applied to the (n−1)th gate line. For example, the fourth scan signal SCAN4 can use the first scan signal SCAN1, the gate line GL of which differs depending on the phase at which the display panel 110 is driven.

The drain electrode of the fifth switching transistor T5 is provided with a stabilization voltage Vini. The source electrode of the fifth switching transistor T5 is connected to the gate electrode of the driving transistor DRT and the storage capacitor Cst.

The fifth switching transistor T5 is turned on by the fourth scan signal SCAN4 to supply a stabilization voltage Vini to the gate electrode of the driving transistor DRT.

The gate electrode of the sixth switching transistor T6 is provided with a third scan signal SCAN3. The source electrode of the sixth switching transistor T6 is provided with a reset voltage VAR. The drain electrode of the sixth switching transistor T6 is connected to the anode of the light emitting element ED.

The sixth switching transistor T6 is turned on by the third scan signal SCAN3 to supply the reset voltage VAR to the anode of the light emitting element ED.

The gate electrode of the seventh switching transistor T7 is provided with a fifth scan signal SCAN5. The source electrode of the seventh switching transistor T7 is provided with a bias voltage VOBS. The drain electrode of the seventh switching transistor T7 is connected to the source electrode of the driving transistor DRT.

Here, the fifth scan signal SCAN5 can be a signal having a different phase from the third scan signal SCAN3 supplied to a subpixel SP in another position. For example, when the third scan signal SCAN3 is applied to the nth gate line, the fifth scan signal SCAN5 can be a third scan signal SCAN3 applied to the (n−1)th gate line. For example, the fifth scan signal SCAN5 can use the third scan signal SCAN3, the gate line GL of which differs depending on the phase at which the display panel 110 is driven.

In addition, since the fifth scan signal SCAN5 is a signal for applying the bias voltage VOBS to the driving transistor DRT, the fifth scan signal SCAN5 can be distinguished from the second scan signal SCAN2 for applying the data voltage Vdata.

The gate electrode of the driving transistor DRT is connected to the drain electrode of the first switching transistor T1. The source electrode of the driving transistor DRT is connected to the drain electrode of the second switching transistor T2. The drain electrode of the driving transistor DRT is connected to the source electrode of the first switching transistor T1.

The driving transistor DRT is turned on due to the difference in voltage between the source electrode and the drain electrode of the driving transistor DRT, and thus the driving current Id is applied to the light emitting element ED.

The source electrode and the drain electrode of the first switching transistor T1 are connected to the drain electrode and gate electrode of the driving transistor DRT, respectively. The operation of sampling and compensating for the threshold voltage of the driving transistor DRT can be activated by the data voltage Vdata applied to the source electrode of the driving transistor DRT in a state in which the first switching transistor T1 is turned on.

One electrode of the storage capacitor Cst is provided with a high-potential driving voltage VDD, and the other electrode of the storage capacitor Cst is connected to the gate electrode of the driving transistor DRT. The storage capacitor Cst stores the voltage of the gate electrode of the driving transistor DRT.

The anode of the light emitting element ED is connected to the drain electrode of the fourth switching transistor T4 and the drain electrode of the sixth switching transistor T6. A low-potential driving voltage VSS is applied to the cathode of the light emitting element ED.

The light emitting element ED generates light having a predetermined luminous intensity using the driving current flowing therethrough due to the driving transistor DRT.

Here, the stabilization voltage Vini is supplied to stabilize changes in capacitance created in the gate electrode of the driving transistor DRT, while the reset voltage VAR is supplied to reset the anode of the light emitting element ED.

When the reset voltage VAR is supplied to the anode of the light emitting element ED in a state in which the fourth switching transistor T4 located between the anode of the light emitting element ED and the driving transistor DRT to be controlled by the emission signal EM is turned off, the anode of the light emitting element ED can be reset.

The sixth switching transistor T6 supplying the reset voltage VAR is connected to the anode of the light emitting element ED.

The fourth scan signal SCAN4 for driving the driving transistor DRT or stabilizing the driving transistor DRT and the third scan signal SCAN3 for controlling the supply of the reset voltage VAR to the anode of the light emitting element ED are separated so that the operation of driving the driving transistor DRT and the operation of resetting the anode of the light emitting element ED can be performed separately.

In this case, the subpixel SP can be configured such that when the switching transistors T5 and T6 supplying the stabilization voltage Vini and the reset voltage VAR are turned on, the fourth switching transistor T4 connecting the drain electrode of the driving transistor DRT and the anode of the light emitting element ED is turned off so as to block flow of the driving current of the driving transistor DRT to the anode of the light emitting element ED and prevent other voltages from having an effect on the anode than the reset voltage VAR.

The subpixel SP including the eight transistors DRT, T1, T2, T3, T4, T5, T6, and T7 and the single capacitor Cst as described above can be referred to as having an 8T1C structure.

The 8T1C structure among a variety of circuit structures of the subpixel SP has been illustrated hereinabove as an example, and the structure and number of the transistors and the capacitors of the subpixel SP can be changed variously. Respective subpixels among the plurality of subpixels SP can have the same structure or some subpixels among the plurality of subpixels SP can have a different structure.

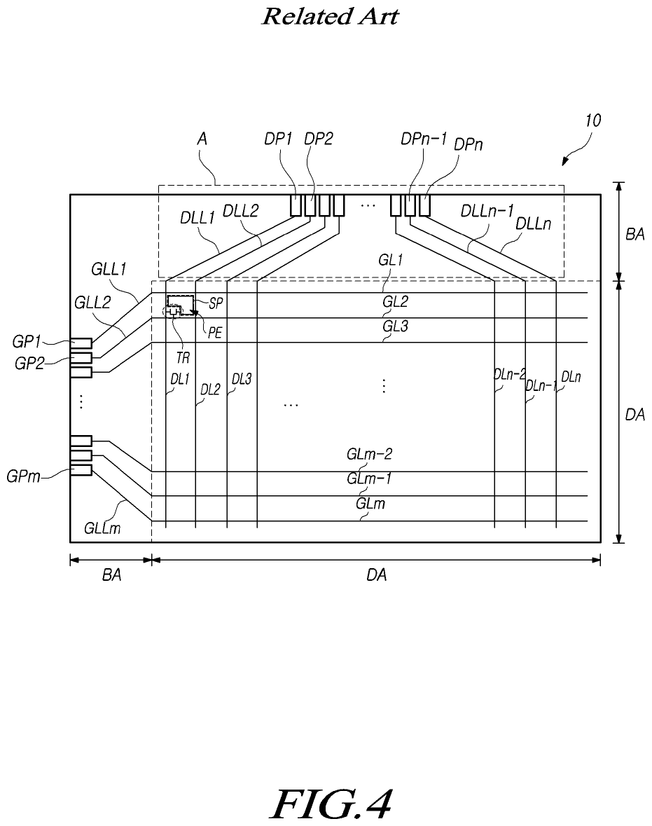

FIG. 4 is a plan diagram illustrating a display panel 10 according to a related art.

Referring to FIG. 4, the display panel 10 can be divided into a display area DA on which images are displayed and a bezel area BA outside the display area DA and on which no images are displayed.

In the display area DA, first to mth gate lines GL1 to GLm to which gate signals are applied in one direction and first to nth data lines DLI to DLn to which data signals are applied in the other direction can be arranged in the form of a matrix, where m and n are positive integers greater than 1. The first to nth data lines DLI to DLn intersect the first to mth gate lines GL1 to GLm to define a plurality of subpixels SP.

A plurality of transistors TR for driving the subpixels SP are provided at intersections of the plurality of gate lines GL1 to GLm and the plurality of data lines DLI to DLn. Pixel electrodes PE in contact with the plurality of transistors TR are provided to correspond to the subpixels SP in a one-to-one relationship.

The plurality of gate lines GL1 to GLm and the plurality of data lines DLI to DLn are connected to a plurality of gate pads GP1 to GPm and a plurality of data pads DP1 to DPn through a plurality of gate link lines GLL1 to GLLm and a plurality of data link lines DLL1 to DLLn formed in the bezel area BA respectively.

Here, the plurality of gate pads GP1 to GPm are electrically connected to a gate driving circuit. An area in which the plurality of gate pads GP1 to GPm are formed corresponds to the area of the gate driving circuit.

In addition, the plurality of data pads DP1 to DPn are electrically connected to a data driving circuit. An area in which the plurality of data pads DP1 to DPn are formed corresponds to the area of the data driving circuit.

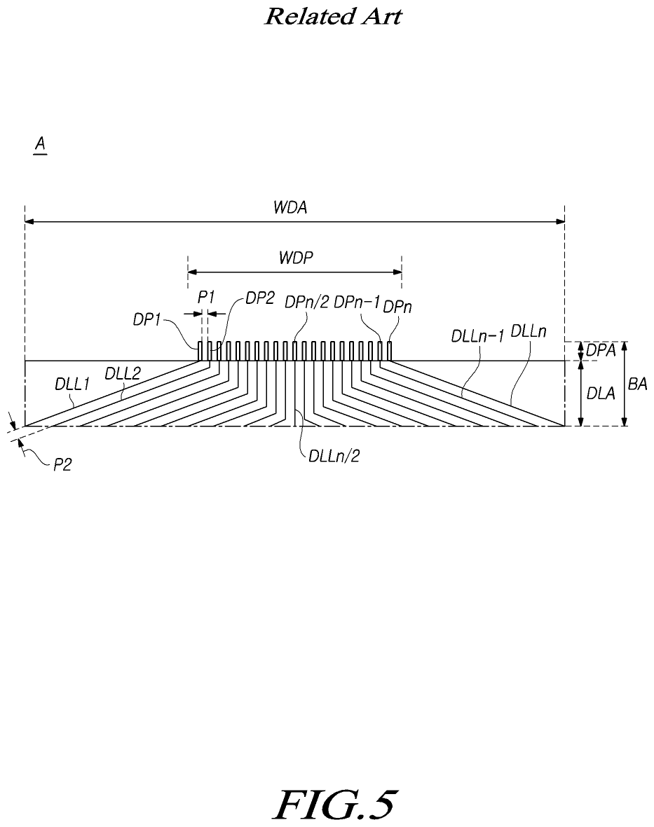

FIG. 5 is an enlarged diagram of the part A in FIG. 4.

Referring to FIG. 5, the bezel area BA adjacent to the data driving circuit can include a data link area DLA in which the data link lines DLL1 to DLLn are formed and a data pad part DPA in which the data pads DP1 to DPn are formed.

The plurality of data pads DP1 to DPn formed in the data pad part DPA are spaced apart from each other at predetermined pad pitches P1.

The plurality of data link lines DLL1 to DLLn corresponding to the plurality of data pads DP1 to DPn in a one-to-one relationship serve to apply data signals to the plurality of data lines DLI to DLn.

The width WDP of a data pad part in which the plurality of data pads DP1 to DPn are arranged in the horizontal direction corresponds to the width of the data driving circuit (e.g., 130 in FIG. 2). Since the width of the data driving circuit (e.g., 130 in FIG. 2) is narrower than the width WDA of the display area, the width WDP of the data pad part is narrower than the width WDA of the display area.

Thus, in the display panel 10 of the related art, the plurality of data link lines DLL1 to DLLn have a slant structure. That is, the plurality of data link lines DLL1 to DLLn extend in the form of slants (i.e., slanted lines) from the plurality of data pads DP1 to DPn toward the display panel 110.

Here, the plurality of data link lines DLL1 to DLLn can be designed with the same widths, the plurality of data link lines DLL1 to DLLn can be spaced apart from each other at uniform link pitches P2.

Due to this slant structure, as shown in FIG. 5 of the related art, the lengths of the data link lines in the bezel area BA increase in the direction of from the central data link line DLLn/2 to the left data link line. The lengths of the data link lines also increase in the direction of from central data link line DLLn/2 to the right data link line.

Here, the thickness of the data link area DLA can be determined in consideration of the difference between the width WDP of the data pad part and the width WDA of the display area and the link pitches P2 of the plurality of data link lines DLL1 to DLLn.

For example, the greater the difference between the width WDP of the data pad part and the width WDA of the display area, the closer the plurality of data link lines DLL1 and DLLn are to the horizon. Thus, in the related art, it is needed to increase the distances between the data pads and the display area DA in consideration of the link pitches P2 of the plurality of data link lines DLL1 to DLLn.

In particular, the greater the size or the higher the resolution of the display device 100, the greater the number of the data lines DL and the number of data link lines DLL are. As a result, the width of the data link area DLA is increased, thereby increasing the size of the bezel area BA.

In order to address this limitation of the related art, a lightweight narrow bezel may be implemented by disposing some data link lines DLL in the display area DA of the display panel. However, when some data link lines DLL are disposed in the display area DA of the display panel, coupling capacitance can be formed between signal lines arranged in parallel at adjacent positions and it can induce deterioration in image quality, which creates another limitation.

Accordingly, in order to address all these limitations associated with the related art, the display device 100 according to examples of the present disclosure can provide and implement a narrow bezel and improve image quality by forming data link lines DLL in a display area DA of a display panel 110 in stepped line structures.

For this purpose, the display device 100 of the present disclosure can divide the data line DL disposed on the display panel 110 into a plurality of data lines, and can connect a plurality of data lines with the data link line with a straight line structure or a stepped line structure.

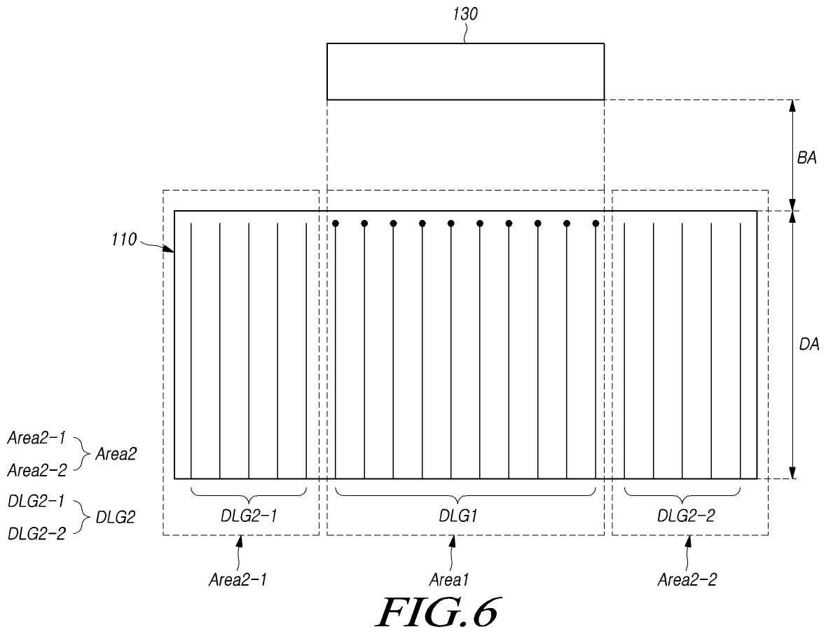

FIG. 6 is a diagram showing an example of a plurality of data lines based on locations in a display device according to embodiments of the present disclosure.

Referring to FIG. 6, the display panel 110 in the display device 100 according to the present disclosure can be divided into a display area DA on which images are displayed and a bezel area BA outside the display area DA and on which no images are displayed.

A plurality of data lines DL extending in a first direction (e.g., a column direction) to receive data signals output from the data driving circuit 130 can be disposed in the display area DA. A plurality of gate lines GL extending in a second direction (e.g., a row direction) to receive gate signals output from the gate driving circuit 120 can be disposed in the display area DA. A plurality of subpixels SP can be formed in areas in which the gate lines GL intersect the data lines DL.

Here, for the convenience of description, the gate lines GL are omitted, and only the data lines DL are depicted in display area DA.

The plurality of data lines DL can be divided into a plurality of first data lines DLG1 disposed in a first area Area1 and a plurality of second data lines DLG2 disposed in on one or more second areas Area2.

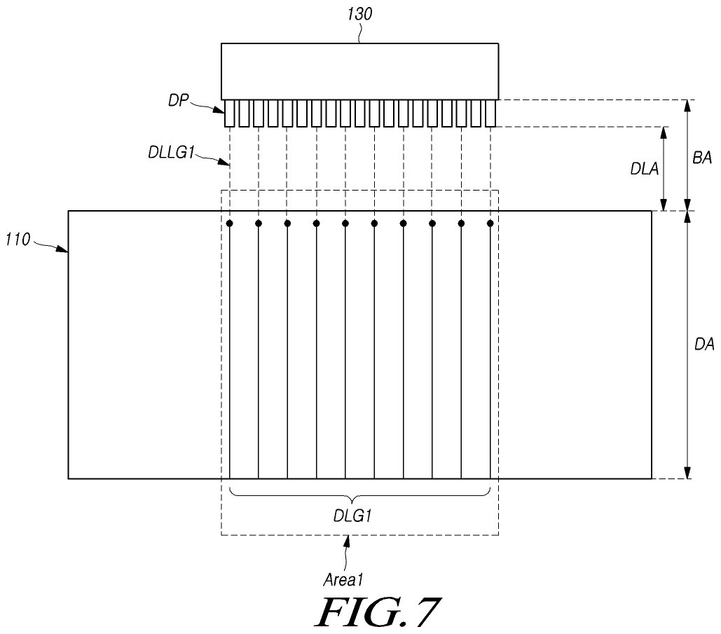

The first area Area1 can correspond to the width of the data driving circuit 130 in the display area DA of the display panel 110. For example, the width of the data driving circuit 130 can be the same as the width of the first area Area1. Since the first area Area1 corresponds to the data driving circuit 130 in the first direction (column direction), the plurality of first data lines DLG1 disposed in the first area Area1 can be connected to the data driving circuit 130 through a plurality of first data link lines extending in a straight line structure. For example, the straight line structure is a structure where the first data link lines extend in straight lines and are not slanted, stepped, or otherwise angled. The first area Area1 will be discussed more below referring to FIG. 7.

The second area Area2 corresponds to an outer area outside the width or ends of the data driving circuit 130 in the display area DA of the display panel 110. The second area Area2 can include a (2-1)th area Area2-1 located on one side (e.g., left side) of the display panel 110 and a (2-2)th area Area2-2 located on another side (e.g., right side) of the display panel 110. As a variation, these second areas can be disposed at different sides of the display panel 110, e.g., top and bottom, etc. depending on the location of the data driving circuit 130.

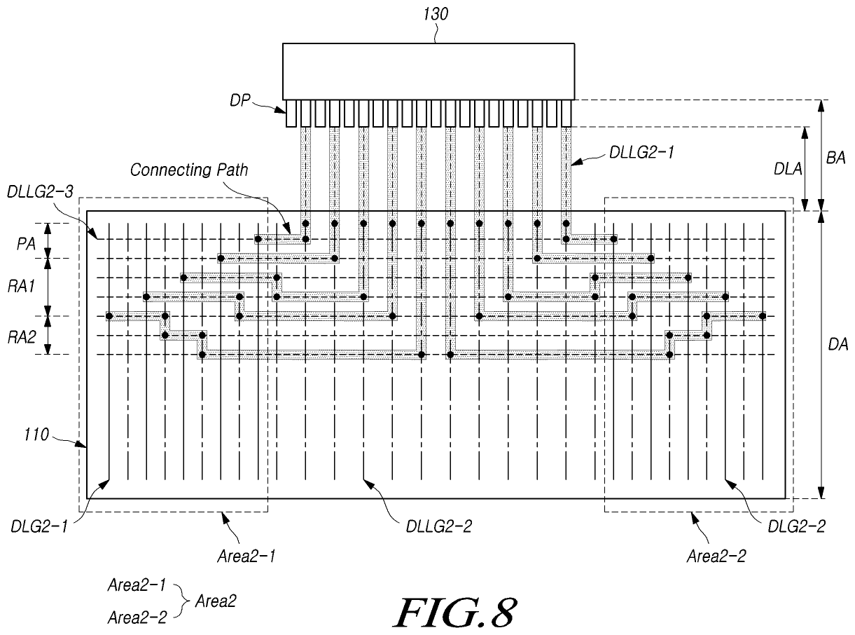

The plurality of second data lines DLG2 can include a plurality of (2-1)th data lines DLG2-1 disposed in the (2-1)th area Area2-1 and a plurality of (2-2)th data lines DLG2-2 disposed in the (2-2)th area Area2-2. The plurality of second data lines DLG2 disposed in the second area Area2 can be connected to the driving circuit 130 through a plurality of second data link lines with a stepped line structure in the display area DA of the display panel 110. The stepped line structure will be discussed later in more detail by referring to some figures such as FIGS. 8, 9 and 19.

FIG. 7 is a diagram illustrating a connecting structure of data lines disposed in the first area Area1 corresponding to the data driving circuit in the display device according to embodiments of the present disclosure.

Referring to FIG. 7, in the display device 100 according to the embodiments of the present disclosure, the first area Area1 corresponding to the data driving circuit 130 is a portion of the display area DA of the display panel 110 corresponding to the width of the data driving circuit 130.

Since the first area Area1 is an area corresponding to (e.g., having the same width as) the data driving circuit 130 in the first direction (e.g., a column direction), the plurality of the first data lines DLG1 disposed in the first area Area1 can be directly connected to the plurality of data pads DP through the plurality of first data link lines DLLG1.

The plurality of first data link lines DLLG1 extend in a straight line form/structure (e.g., in straight lines) from the plurality of data pads DP, and are directly connected to the plurality of first data lines DLG1 disposed in the first area Area1 corresponding to the data driving circuit 130. Thus, the plurality of first data link lines DLLG1 can be disposed in the data link area DLA, but do not extend through the display area DA.

FIG. 8 is a diagram separately illustrating a connecting structure of the plurality of second data lines disposed in the second areas located outside of the first area in the display device according to embodiments of the present disclosure. Here, the data link lines and data lines associated with the first area Area1 of FIG. 7 are not shown, so as better illustrate the lines associated with the second areas.

Referring to FIG. 8, in the display device 100 according to the embodiments of the present disclosure, the second area Area2 located outside of the first area Area1 corresponds to portions of the display area DA of the display panel 110 disposed on both sides of the first area Area1. The second area Area2 can include the (2-1)th area Area2-1 located on the left side of the display panel 110 and the (2-2)th area Area2-2 located on the right side of the display panel 110.

The plurality of second data lines DLG2 disposed in the second area Area2 can be connected to the plurality of data pads DP through the plurality of second data link lines DLLG2 with a stepped line structure.

The plurality of second data link lines DLLG2 can include a plurality of (2-1)th data link lines DLLG2-1 extending in a first direction (e.g., column direction) in the bezel area BA, a plurality of (2-2)th data link lines DLLG2-2 extending in the first direction (column direction) in the display area DA of the display panel 110, and a plurality of (2-3)th data link lines DLLG2-3 extending in a second direction (e.g., row direction) in the display area DA of the display panel 110. The first and second directions can be perpendicular to each other. Further, the plurality of (2-2)th data link lines DLLG2-2 extend directly from plurality of (2-1)th data link lines DLLG2-1, in the display area DA.

The plurality of (2-1)th data link lines DLLG2-1 located in the bezel area BA are extended to the first area Area1 corresponding to the data driving circuit 130, from the plurality of data pads DP along the first direction (column direction).

The plurality of (2-2)th data link lines DLLG2-2 are disposed parallel to the plurality of first data lines DLG1 in the first area Area1 (FIG. 7) and to the plurality of second data lines DLG2 in the second area Area2. The plurality of (2-2)th data link lines DLLG2-2 can all have same lengths to form equal capacitance.

Each of the plurality of (2-1)th data link lines DLLG2-1 disposed in the bezel area BA is connected to a corresponding one of the plurality of (2-2)th data link lines DLLG2-2 located in the first area Area1. The plurality of (2-1)th data link lines DLLG2-1 can be connected to the plurality of (2-2)th data link lines DLLG2-2 through contact holes. The data link lines DLLG2-1 and DLLG2-2 are connected to each other and form straight lines.

The plurality of (2-3)th data link lines DLLG2-3 are extended in the second direction (row direction) in the display area DA. The plurality of (2-3)th data link lines DLLG2-3 can be connected to the plurality of second data lines DLG2 disposed in the second area Area2 through contact holes. The plurality of (2-3)th data link lines DLLG2-3 can all have the same lengths to form equal capacitance.

In the display device 100 of the present disclosure, at least some of the plurality of second data lines DLG2 disposed in the second area Area2 can be connected with a plurality of (2-3)th data link lines DLLG2-3 and a plurality of (2-2)th data link lines DLLG2-2 in a stepped line structure/configuration, in order to reduce the coupling capacitance formed between the plurality of (2-3)th data link lines DLLG2-3 and adjacent signal lines.

For example, some data lines in a straight area PA within a reference distance from the data pad DP among the plurality of (2-1)th data lines DLG2-1 located in the (2-1)th area Area2-1 of the display panel 110 can be connected with the plurality of (2-3)th data link lines DLLG2-3 with a straight line structure/configuration (e.g., in a horizontal line configuration).

On the other hand, some data lines in a first step area RA1 that are disposed further than the reference distance among the plurality of (2-1)th data lines DLG2-1 can connect the plurality of (2-2)th data link lines DLLG2-2 and the plurality of (2-3)th data link lines DLLG2-3 in a one-stage stepped line structure/configuration. In addition, some data lines in a second step area RA2 among the plurality of (2-1)th data lines DLG2-1 can connect the plurality of (2-2)th data link lines DLLG2-2 and the plurality of (2-3)th data link line DLLG2-3 in a two-stage stepped line structure/configuration. As an example, the one-stage stepped line structure/configuration in the first step area RA1 can include one step as the line extends, whereas the two-stage stepped line structure/configuration in the second step area RA2 can include two steps as the line extends.

Further, the straight area PA is followed by the first step area RA1, which is followed by the second step area RA2.

Similarly, some data lines in the straight area PA within a reference distance from the data pad DP among the plurality of (2-2)th data lines DLG2-2 located in the (2-2)th area Area2-2 of the display panel 110 can be connected with the plurality of (2-3)th data link lines DLLG2-3 with a straight line structure/configuration.

Some data lines in the first step area RA1 that are disposed further than the reference distance among the plurality of (2-2)th data lines DLG2-2 can connect the plurality of (2-2)th data link lines DLLG2-2 and the plurality of (2-3)th data link lines DLLG2-3 in a one-stage stepped line structure/configuration, and some data lines among the plurality of (2-2)th data lines DLG2-2 in the second step area RA2 can connect the plurality of (2-2)th data link lines DLLG2-2 and the plurality of (2-3)th data link line DLLG2-3 in a two-stage stepped line structure/configuration.

For example, the plurality of second data lines DLG2 disposed in the second area Area2 of the display panel 110 can be connected to the data driving circuit 130 through the plurality of (2-2)th data link lines DLLG2-2 and the plurality of (2-3)th data link lines DLLG2-3 with the stepped line structure/configuration in the display area DA of the display panel 110 depending on their positions.

In this way, when the plurality of (2-2)th data link lines DLLG2-2 and the plurality of (2-3) data link lines DLLG2-3 disposed in the display area DA are connected in a stepped line structure, the coupling capacitance between adjacent signal lines in the display panel 110 can be reduced or minimized according to the present disclosure.

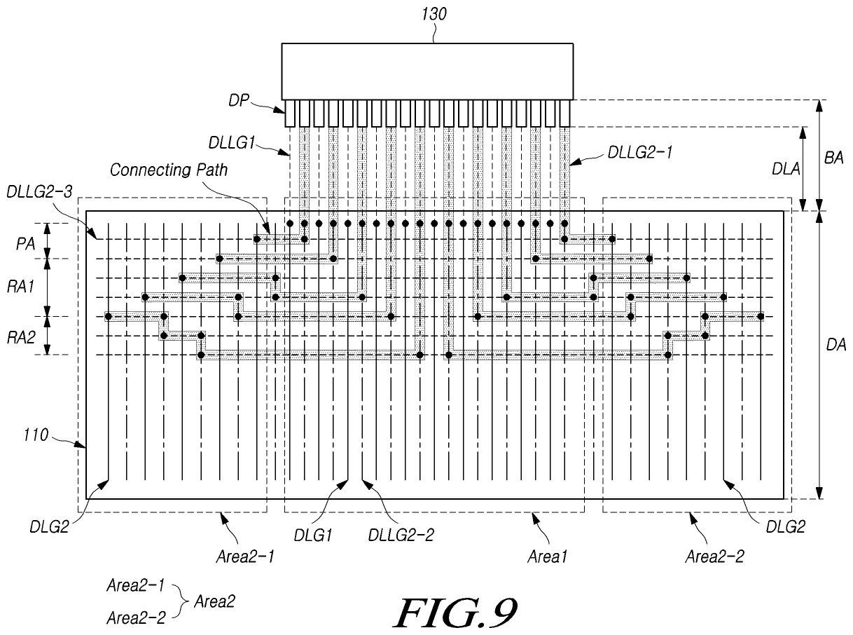

FIG. 9 is a plan view illustrating the structure of a display panel according to embodiments of disclosure. The structure shown in FIG. 9 is the combined view of FIGS. 7 and 8.

Referring to FIG. 9, the display panel 110 according to the embodiments of disclosure can include the display area DA for displaying the image and the bezel area BA where the image is not displayed outside the display area DA.

The plurality of data lines DL disposed on the display panel 110 can include the plurality of first data lines DLG1 disposed in the first area Area1 and the plurality of second data lines DLG2 disposed in the second area Area2.

Since the first area Area1 is an area corresponding to the data driving circuit 130 in the first direction (column direction), the plurality of first data lines DLG1 disposed in the first area Area1 can be directly connected to the plurality of data pads DP through the plurality of first data link lines DLLG1.

The plurality of second data lines DLG2 disposed in the second area Area2 can be connected to the data driving circuit 130 through the plurality of (2-2)th data link lines DLLG2-2 and the plurality of (2-3)th data link lines DLLG2-3 with the stepped line structure/configuration.

At this time, the plurality of (2-2)th data link lines DLLG2-2 and the plurality of (2-3)th data link lines DLLG2-3 can have a central downward stepped line structure that goes downward toward the center of the display panel 110, or can have an outer downward stepped line structure that goes downward toward the outer edge of the display panel 110. Here, it illustrates the plurality of (2-2)th data link lines DLLG2-2 and the plurality of (2-3)th data link lines DLLG2-3 have a central downward stepped line structure that goes downward toward the center of the display panel 110.

In the display device 100 of the present disclosure, it is desirable that the stepped line structure on the left side of the display panel 110 is symmetrical to the stepped line structure on the right side of the display panel 110 with respect to the center or middle line of the display panel 110.

In this way, when the plurality of second data lines DLG2 located in the second area Area2 outside the first area Area1 are connected to the data driving circuit 130 through the plurality of (2-2)th data link lines DLLG2-2 and the plurality of (2-3)th data link lines DLLG2-3 with connecting paths of the stepped line structure, the link pitch between data link lines can be secured even though the distance between the data driving circuit 130 and the display panel 110 is small.

Therefore, it is possible to implement a lightweight narrow bezel due to the narrow width of the data link area DLA in a display device.

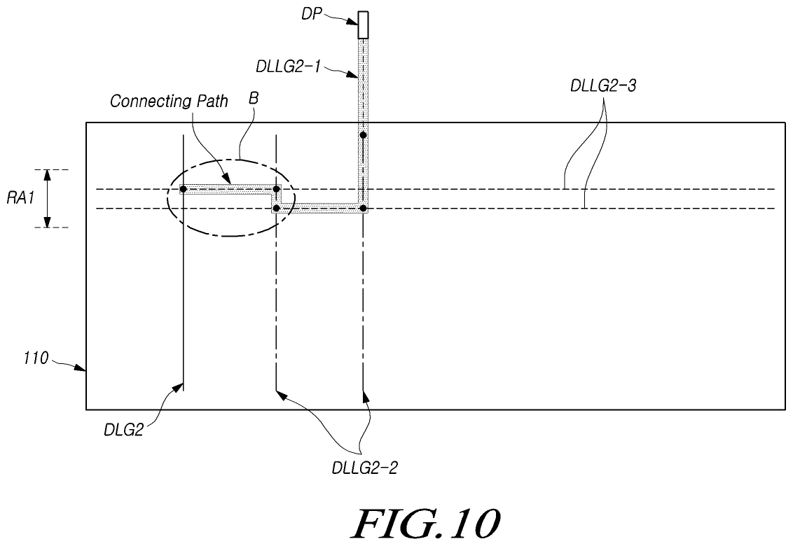

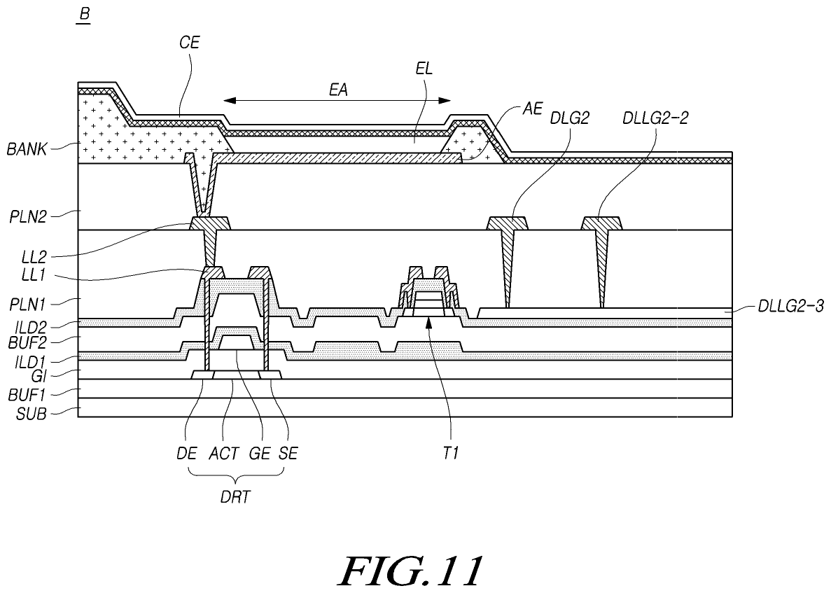

FIG. 10 is a plan view showing a portion of data lines and data link lines in a display panel according to embodiments of the present disclosure, and FIG. 11 is a cross-sectional view showing area B of FIG. 10.

Referring to FIG. 10 and FIG. 11, the plurality of second data lines DLG2 located in the second area Area2 outside the first area Area1 in the display panel 110 according to the embodiments of the present disclosure can be connected through the plurality of (2-3)th data link lines DLLG2-3 and the plurality of (2-2)th data link lines DLLG2-2 with or in a stepped line structure/configuration.

For example, some data lines connected in the first step area RA1 among the plurality of (2-1)th data lines DLG2-1 located in the (2-1)th area Area2-1 of the display panel 110 can connect the plurality of (2-2)th data link lines DLLG2-2 and the plurality of (2-3)th data link lines DLLG2-3 in a one-stage stepped line structure/configuration.

This stepped line structure in cross-sectional view as shown in the area B of FIG. 10 will now be discussed referring to FIG. 11 as follows.

The display panel 110 of the display device 100 according to the embodiments of disclosure includes a substrate SUB.

The plurality of subpixels SP are formed on the substrate SUB. Each of the plurality of subpixels SP includes the light emitting element ED which is comprised of an anode electrode AE, a light emitting layer EL, and a cathode electrode CE, a driving transistor DRT for driving the light emitting element ED, and a storage capacitor Cst to maintain the voltage between a gate electrode GE and a source electrode SE (or drain electrode DE) of the driving transistor DRT.

The driving transistor DRT, the switching transistor, the capacitor Cst and the light emitting elements ED can be formed on the substrate SUB. The drain electrode DE of the driving transistor DRT can be electrically connected to the anode electrode AE of the light emitting element ED. Here, it illustrates a case where the driving transistor DRT and the first switching transistor T1 are formed as an example.

An encapsulation layer can be formed on the cathode electrode CE of the light emitting element ED. The encapsulation layer can prevent oxygen or moisture from penetrating into the light emitting elements ED.

A first buffer layer BUF1 can be disposed on the substrate SUB. The driving transistor DRT can be formed on the first buffer layer BUF1.

A semiconductor layer ACT, a source electrode SE, and a drain electrode DE of the driving transistor DRT can be formed on the first buffer layer BUF1.

A gate insulating film GI can be disposed on the semiconductor layer ACT, the source electrode SE, and the drain electrode DE of the driving transistor DRT.

The gate electrode GE of the driving transistor DRT can be formed on the gate insulating film GI.

A first interlayer insulating film ILD1 can be disposed on the gate electrode GE of the driving transistor DRT. A second buffer layer BUF2 can be disposed on the first interlayer insulating film ILD1.

The first switching transistor T1 can be formed on the second buffer layer BUF2. Here, the first switching transistor T1 is shown as an example among a plurality of switching transistors.

A second interlayer insulating film ILD2 can be disposed to cover the first switching transistor T1.

A semiconductor layer, a source electrode, and a drain electrode of the first switching transistor T1 can be disposed on the second interlayer insulating film ILD2.

A second gate insulating film and a gate electrode of the first switching transistor T1 can be sequentially disposed on the semiconductor layer, the source electrode, and the drain electrode of the first switching transistor T1.

A first link line LL1 connecting the source electrode SE and the drain electrode DE of the driving transistor DRT can be disposed on the second interlayer insulating film ILD2. Likewise, a first link line connecting the source electrode and the drain electrode of the first switching transistor T1 can be disposed on the second interlayer insulating film ILD2.

The source electrode SE and the drain electrode DE of the driving transistor DRT can be electrically connected to the first link line LL1 through a contact hole on or thru the second interlayer insulating film ILD2.

Additionally, a (2-3)th data link line DLLG2-3 extending in one direction can be disposed on the second interlayer insulating film ILD2.

The (2-3)th data link line DLLG2-3 can be extended in parallel to the gate lines GL between the gate lines GL. The (2-3)th data link line DLLG2-3 can be made of the same material as the source electrode SE or the drain electrode DE of the driving transistor DRT.

A first planarization layer PLN1 can be disposed on the second interlayer insulating film ILD2 and the (2-3)th data link line DLLG2-3, covering the first link line LL1.

A second link line LL2 transferring a driving current to the light emitting element ED and a second data line DLG2 transferring a data voltage Vdata can be disposed on the first planarization layer PLN1. Additionally, a (2-2)th data link line DLLG2-2 extending in the same direction as the second data line DLG2 can be disposed on the first planarization layer PLN1.

The second link line LL2, the second data line DLG2, and the (2-2)th data link line DLLG2-2 can be made of the same material as the source electrode SE or the drain electrode DE of the driving transistor DRT.

The second link line LL2 can be formed for electrical connection between the source electrode SE or drain electrode DE of the driving transistor DRT and the anode electrode AE of the light emitting element ED, and can be placed in a position overlapping with the anode electrode AE.

The second data line DLG2 and the (2-2)th data link line DLLG2-2 located on connecting paths of the stepped line structure can be electrically connected to the (2-3)th data link line DLLG2-3 through a contact hole.

For example, the (2-2)th data link line DLLG2-2 can be formed on the same layer and of the same material as the second data line DLG2.

A second planarization layer PLN2 can be disposed on the first planarization layer PLN1 to cover the second link line LL2, the second data line DLG2, and the (2-2)th data link line DLLG2-2.

The anode electrode AE can be disposed on the second planarization layer PLN2 at a point defined by the light emitting area EA of the subpixel SP. The anode electrode AE can be connected to the second link line LL2 through an anode contact hole formed on the second planarization layer PLN2. Accordingly, the anode electrode AE can be electrically connected to the source electrode SE of the driving transistor DRT through the first link line LL1 and the second link line LL2.

Additionally, a bank BANK can be disposed on the anode electrode AE to define the light emitting area EA of the subpixel SP. A part of the anode electrode AE of the light emitting element ED can be exposed through a part of the bank BANK. Therefore, the open area of the bank BANK can correspond to the light emitting area EA.

The light emitting layer EL of the light emitting element ED can be disposed on the anode electrode AE exposed by the open area of the bank BANK, and the cathode electrode CE of the light emitting element ED can be disposed on the light emitting layer EL.

As such, the second data line DLG2 located in the second area Area2 in the display panel 110 of the present disclosure can be connected through the (2-2)th data link line DLLG2-2 and the (2-3)th data link line DLLG2-3 in a stepped line structure in different layers.

As a result, the display device 100 of the present disclosure can reduce the width of the data link area DLA to implement a lightweight narrow bezel, while reducing the coupling capacitance associated with adjacent signal lines and improving image quality of the display device 100.

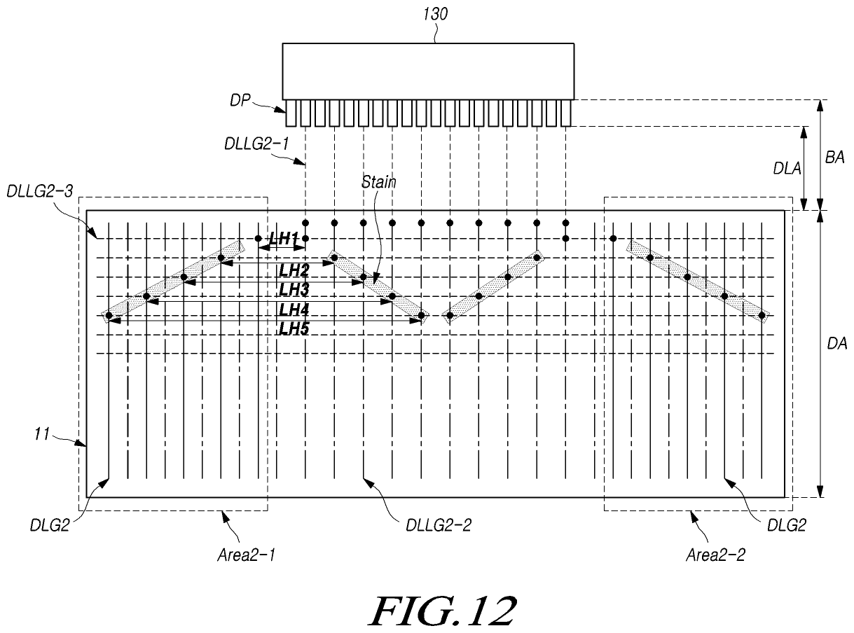

The limitation of having the coupling capacitance and stains will now be discussed referring to FIGS. 12-14.

FIG. 12 is a diagram illustrating a case in which a stain is formed in an area due to the data link lines arranged in a straight line structure in a row direction.

Referring to FIG. 12, in a display panel 11 of a display device according to an example of the present disclosure, the plurality of second data line DLG2 disposed in the second area Area2 outside of the first area Area1 can be connected using the plurality of (2-1)th data link lines DLLG2-1, the plurality of (2-2)th data link lines DLLG2-2 and the plurality of (2-3)th data link lines DLLG2-3, in a straight line configuration.

At this time, the lengths LH1-LH5 of the plurality of (2-3)th data link lines DLLG2-3 connecting between the plurality of (2-2)th data link lines DLLG2-2 disposed in the first area Area1 and the plurality of second data lines DLG2 disposed in the second area Area2 can be different from each other.

However, when the plurality of (2-3)th data link lines DLLG2-3 are formed in a straight line structure/configuration in a row direction within the display area DA of the display panel 11, image quality can be degraded due to coupling capacitance between signal lines disposed in parallel at adjacent positions.

As a result, stains having different luminance can appear along a bending point where the plurality of second data lines DLG2 and the plurality of (2-3)th data link lines DLLG2-3 are connected in the display panel 11.

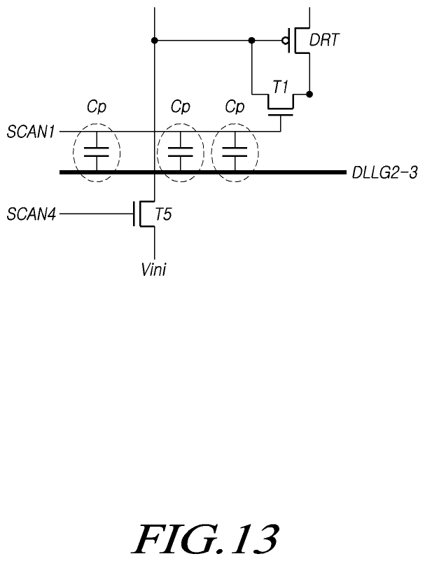

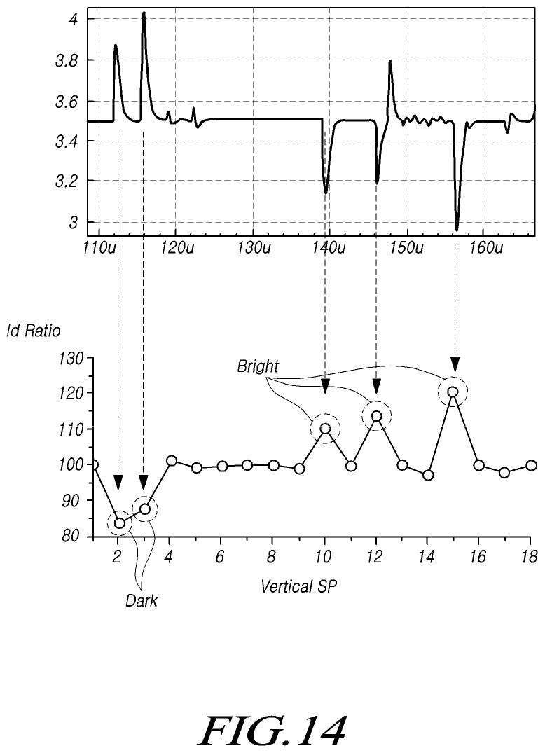

FIG. 13 is a circuit diagram illustrating a phenomenon in which coupling capacitance is formed due to the (2-3)th data link lines disposed in a straight line structure in a row direction in the display area of the display panel 11, and FIG. 14 is an experimental diagram illustrating a variation of driving current flowing in subpixels in a column direction when the (2-3)th data link lines in row direction are formed in a straight line structure in the display area of the display panel 11.

Referring to FIGS. 13 and 14, when the plurality of (2-3)th data link lines DLLG2-3 are formed in a straight line structure within the display area DA of the display panel 11, coupling capacitance can be formed with signal lines disposed in parallel at adjacent positions.

For example, a plurality of signal lines for transferring scan signals can be located in the subpixel SP, and the (2-3)th data link lines DLLG2-3 can be arranged in parallel with a signal line transferring a first scan signal SCAN1 to a first switching transistor T1. As such, when the (2-3)th data link lines DLLG2-3 are arranged parallel to the signal line transferring the first scan signal SCAN1, a coupling capacitance Cp is formed between the (2-3)th data link lines DLLG2-3 and the signal line transferring the first scan signal SCAN1.

The coupling capacitance Cp increases in proportion to the length in which the (2-3)th data link lines DLLG2-3 and the signal line supplying the first scan signal SCAN1 are arranged side by side.

As such, when a data voltage Vdata is supplied through the (2-3)th data link lines DLLG2-3 in a state where the coupling capacitance Cp is formed between the (2-3)th data link lines DLLG2-3 and the signal line transferring the first scan signal SCAN1, the data voltage Vdata varies and the driving current Id flowing through the light emitting element ED changes due to the coupling capacitance Cp, resulting in luminance deviation.

As a result, a luminance difference occurs along the contact holes connecting the plurality of second data lines DLG2 and the (2-3)th data link lines DLLG2-3, and stains can appear.

Signal lines that can be disposed in parallel to the (2-3)th data link lines DLLG2-3 are not only the signal line for supplying the first scan signal SCAN1, but can also be various signal lines, such as a signal line for supplying a second scan signal SCAN2 or a signal line for supplying a fourth scan signal SCAN4.

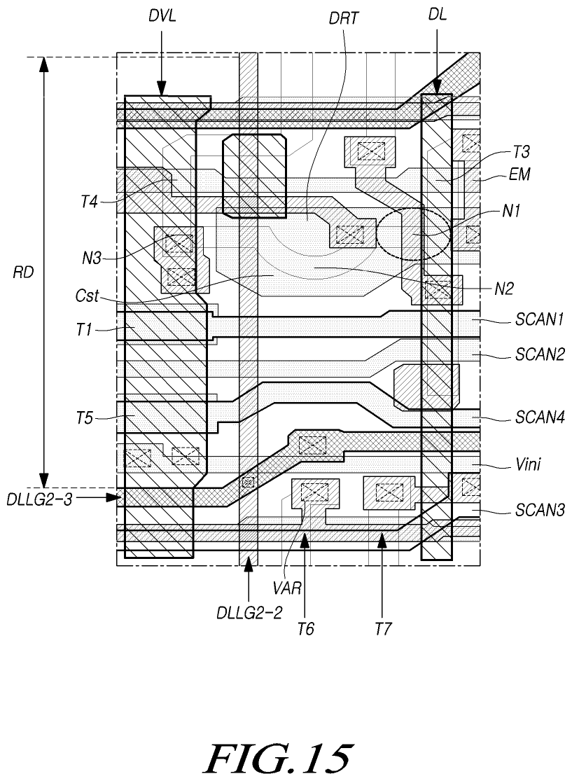

To address this limitation, the display device 100 according to the present disclosure is provided, which can reduce the coupling capacitance (e.g., Cp) formed between the plurality of (2-3)th data link lines DLLG2-3 and other adjacent signal lines, and can improve image quality, by forming the plurality of (2-3)th data link lines DLLG2-3 connecting between the plurality of second data lines DLG2 disposed in the second area Area2 and the plurality of (2-2)th data link lines DLLG2-2 located in the first area Area1 in a stepped line structure/configuration, which will now be discussed referring to FIGS. 15-18.

FIG. 15 is a diagram illustrating a plan view of a subpixel with the plurality of second data link lines with connecting paths of a stepped line structure in a display device according to embodiments of the present disclosure. Here, it shows a plan view corresponding to the subpixel circuit shown in FIG. 3 as an example.

Referring to FIG. 15, the display device 100 according to embodiments of disclosure can include at least a part of the plurality of (2-3)th data link lines DLLG2-3 located in the display area DA formed in a stepped line structure/configuration in order to reduce coupling capacitance between the plurality of (2-3)th data link lines DLLG2-3 and adjacent signal lines.

For example, the display device 100 of the present disclosure can reduce the coupling capacitance between adjacent signal lines by forming the plurality of (2-3)th data link lines DLLG2-3 located in the display area DA in a stepped line structure having a constant step width RD according to positions but not extending in a horizontal direction.

In this way, when the plurality of (2-3)th data link lines DLLG2-3 located in the display area DA are formed in stepped line structure having a constant step width RD, the coupling capacitance can be reduced because the length of the plurality of (2-3)th data link lines DLLG2-3 arranged in parallel with adjacent signal lines are reduced.

At this time, it is preferable that the step width RD in a stepped line structure of the plurality of (2-3)th data link lines DLLG2-3 is formed at a distance sufficient to reduce the coupling phenomenon by the adjacent signal line. For example, when a plurality of signal lines are disposed in the step width RD of the plurality of (2-3)th data link lines DLLG2-3, the coupling phenomenon can be reduced or minimized since the coupling capacitance formed in the plurality of (2-3)th data link lines DLLG2-3 is distributed by the plurality of signal lines.

Therefore, it is preferable to form the step width RD of the plurality of (2-3)th data link lines DLLG2-3 to correspond to the size in which a plurality of signal lines are arranged or to form them to be more than the width of a plurality of subpixels SP in order to reduce the coupling phenomenon caused by the plurality of (2-3)th data link lines DLLG2-3.

In addition, in a display period for displaying an image on the display panel 110 or a sensing period for detecting the characteristic value (threshold voltage or mobility) of the subpixel SP in the display panel 110, a coupling capacitance Cp can increase at the time when the voltage of the source electrode NI of the driving transistor DRT increases due to a data voltage Vdata supplied to the driving transistor DRT in state that the first switching transistor T1 connecting the gate electrode and the drain electrode of the driving transistor DRT is turned on.

Accordingly, the display device 100 of the present disclosure can have locations where the plurality of (2-3)th data link lines DLLG2-3 are bent in a stepped line structure with a certain distance or more from the source electrode NI of the driving transistor DRT.

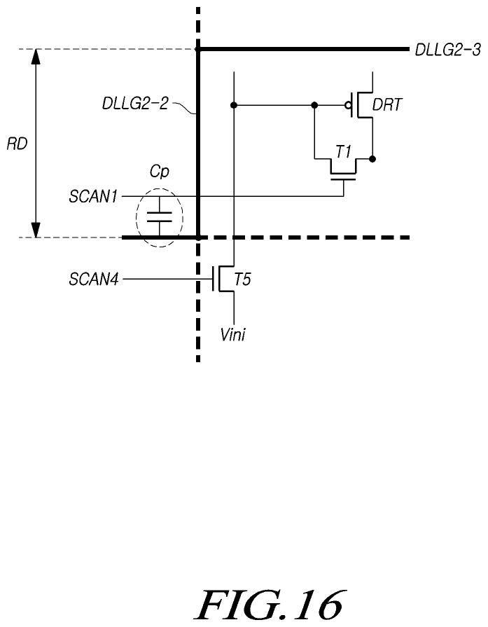

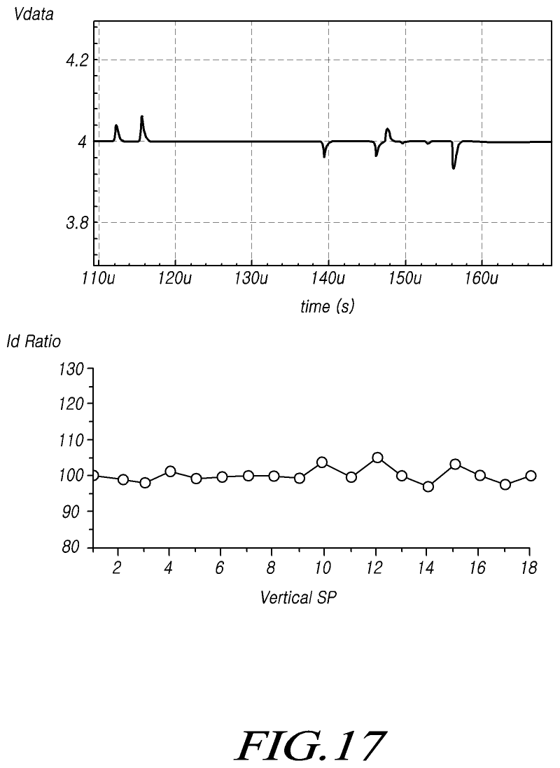

FIG. 16 is a circuit diagram illustrating a phenomenon in which coupling capacitance is formed due to the plurality of (2-3)th data link lines with connecting paths of a stepped line structure in the display area of the display panel 110 of the present disclosure, and FIG. 17 is an experimental diagram illustrating a variation of driving current flowing in subpixels when the plurality of (2-3)th data link lines with connecting paths in a stepped line structure are connected to the plurality of (2-2)th data link lines in the display area of the display panel 110 of the present disclosure.

Referring to FIGS. 16 and 17, the plurality of (2-3)th data link lines DLLG2-3 located in the display area DA of the display panel 110 of the display device 100 according to the present disclosure can form a coupling capacitance with a signal line, for example, the first scan signal line disposed in parallel at an adjacent position.

The coupling capacitance Cp increases in proportion to the length in which the plurality of (2-3)th data link lines DLLG2-3 and the first scan signal line supplying the first scan signal SCAN1 are arranged side by side.

However, since at least a part of the plurality of (2-3)th data link lines DLLG2-3 located in the display area DA is connected to the plurality of (2-2)th data link lines DLLG2-2 located on a different layer in a stepped line structure in the display device 100 according to the embodiments of the present disclosure, the length in which adjacent signal lines are arranged in parallel with the plurality of (2-3)th data link lines DLLG2-3 in the stepped line structure is shortened, so that the coupling capacitance can be reduced or minimized.

For example, the plurality of (2-3)th data link lines DLLG2-3 in a stepped line structure are arranged in parallel with the signal line for supplying the first scan signal SCAN1 in a partial area, thereby coupling capacitance Cp can be formed. However, since the plurality of (2-3)th data link lines DLLG2-3 are formed in the stepped line structure/configuration having a constant step width RD through the plurality of (2-2)th data link lines DLLG2-2 located on a different layer, the length parallel to the signal line for supplying the first scan signal SCAN1 is reduced or minimized and the coupling capacitance Cp can be reduced or minimized.

In addition, when a plurality of scan signal lines are arranged in the area corresponding to the step width RD of the plurality of (2-3)th data link lines DLLG2-3, the coupling capacitance Cp can be reduced or minimized since the coupling capacitance Cp formed in the plurality of (2-3)th data link lines DLLG2-3 is distributed by a plurality of scan signal lines.

Therefore, it is effective that the step width RD for connecting the plurality of (2-3)th data link lines DLLG2-3 in a stepped line structure is larger than the width at which a plurality of scan signal lines can be arranged or the width of the unit subpixel SP.

In this way, in a state in which the coupling capacitance Cp formed at the plurality of (2-3)th data link lines DLLG2-3 in a stepped line structure is reduced, image quality can be improved since the variation of the data voltage Vdata and the driving current Id is reduced while the data voltage Vdata is supplied to the plurality of (2-3)th data link lines DLLG2-3.

As a result, the luminance deviation along the contact holes connecting the second data lines DLG2 disposed in the second area Area2 to the plurality of (2-3)th data link lines DLG2-3 is reduced and stains can decrease or be minimized or eliminated.

Accordingly, the display device 100 of the present disclosure can reduce or minimize the coupling capacitance formed on the plurality of (2-3)th data link lines DLLG2-3 and improve image quality, by connecting the plurality of second data lines DLG2 and the plurality of (2-2)th data link lines DLLG2-2 disposed in the second area Area2 through the plurality of (2-3)th data link lines DLLG2-3 in a stepped line structure/configuration.

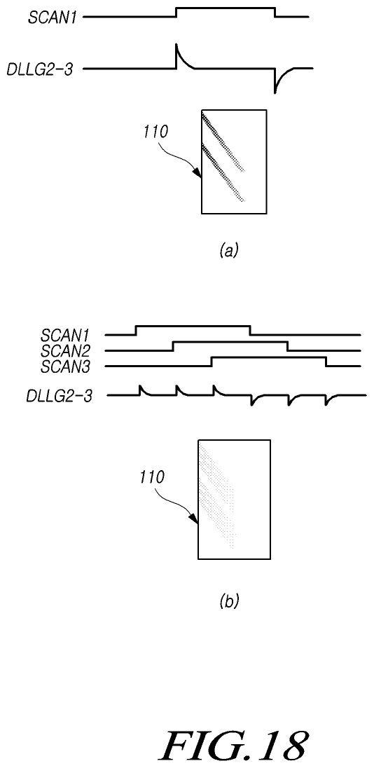

FIG. 18 is a diagram illustrating stains according to shapes of the plurality of (2-3)th data link lines in a display device according to a comparison example and an example of the present disclosure, where the comparison example can be a different of the present disclosure.

Referring to the comparison example (a) of FIG. 18, when the plurality of (2-3)th data link lines DLLG2-3 connecting between the plurality of (2-2)th data link lines DLLG2-2 disposed in the first area Area1 and the plurality of second data lines DLG2 disposed in the second area Area2 in the display device have a straight line structure, stains with different luminance can appear along the contact holes for connecting the plurality of second data lines DLG2 and the plurality of (2-3)th data link lines DLLG2-3 due to some signal lines, for example the first scan signal line.

On the other hand, as shown in (b) of FIG. 18, when the plurality of (2-3)th data link lines DLLG2-3 connecting the plurality of second data lines DLG2 disposed in the second area Area2 to the plurality of (2-2)th data link lines DLLG2-2 located in the first area Area1 have connecting paths of a stepped line structure of the present disclosure, coupling capacitance formed between the plurality of (2-3)th data link lines DLLG2-3 and other signal lines can be reduced or minimized.

In particular, when a plurality of scan signal lines (for example, first to third scan signal lines) are disposed on the step width RD of the plurality of (2-3)th data link lines DLLG2-3, the coupling capacitance can be reduced since the coupling capacitance formed on the plurality of (2-3)th data link lines DLLG2-3 is distributed by a plurality of scan signal lines.

As a result, stains that can be generated along the contact holes for connecting the second data lines DLG2 and the plurality of (2-3)th data link lines DLLG2-3 can be reduced or minimized.

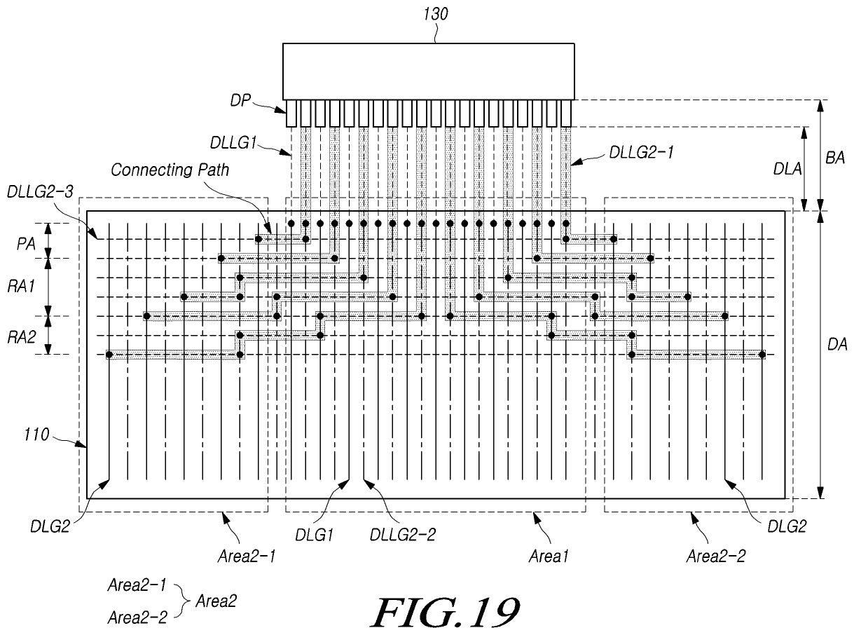

FIG. 19 is a plan view illustrating a structure of a display panel having the (2-3)th data link lines of a different arrangement structure in a display device according to another example of the present disclosure. This example can be the same as or correspond to the example of FIG. 9, but the configuration/shape of the steps defined by the data line and data link line connections (i.e., stepped line structure) differs.

Referring to FIG. 19, the display panel 110 according to this example of the disclosure can be divided into a display area DA on which images are displayed and a bezel area BA outside the display area DA and on which no images are displayed.

The plurality of data lines DL disposed on the display panel 110 can include a plurality of first data lines DLG1 located in the first area Area1 and a plurality of second data lines DLG2 located in the second area Area2.

Since the first area Area1 corresponds to the data driving circuit 130 in the first direction (column direction), the plurality of first data lines DLG1 disposed in the first area Area1 can be directly connected to the plurality of data pads DP through the plurality of first data link lines DLLG1.

The plurality of second data lines DLG2 arranged in the second area Area2 can be connected to the data driving circuit 130 through the plurality of (2-2)th data link lines DLLG2-2 and the plurality of (2-3) data link lines DLLG2-3 with connection paths of a stepped line structure.

At this time, connecting paths of the plurality of (2-2)th data link lines DLLG2-2 and the plurality of (2-3)th data link lines DLLG2-3 can have a central downward stepped line structure that goes downward toward the center of the display panel 110 (e.g., as shown in FIG. 9), or can have an outer downward stepped line structure that goes downward toward the outer edge of the display panel 110 (e.g., as shown in FIG. 19). Here, FIG. 19 illustrates the connecting paths of the plurality of (2-2)th data link lines DLLG2-2 and the plurality of (2-3)th data link lines DLLG2-3 have an outer downward stepped line structure that goes downward toward the outer edge of the display panel 110.

In the display device 100 of the present disclosure, it is desirable that the stepped line structure on the left side of the display panel 110 is symmetrical to the stepped line structure on the right side of the display panel 110 with respect to the center or middle line of the display panel 110.

In this way, when the plurality of second data lines DLG2 located in the second area Area2 outside the first area Area1 are connected to the data driving circuit 130 through the plurality of (2-2)th data link lines DLLG2-2 and the plurality of (2-3)th data link lines DLLG2-3 with connecting paths of a stepped line structure, the link pitch between data link lines can be secured even though the distance between the data driving circuit 130 and the display panel 110 is small.

Therefore, it is possible to implement a lightweight narrow bezel due to the narrow width of the data link area DLA in the display panel 110 of FIG. 19.

Moreover, when the plurality of (2-3)th data link lines DLLG2-3 connecting the second data lines DLG2 disposed in the second area Area2 to the plurality of (2-2)th data link lines DLLG2-2 located in the first area Area1 have connecting paths of stepped line structure, coupling capacitance formed between the plurality of (2-3)th data link lines DLLG2-3 and other signal lines can be reduced in the display panel 110 of FIG. 19.

Now, the above-described embodiments of the present disclosure will be briefly reviewed as follows.

A display device according to embodiments of the present disclosure can include a data driving circuit configured to supply a plurality of data voltages to a plurality of data lines, a gate driving circuit configured to supply a plurality of gate signals to a plurality of gate lines, a display panel having a plurality of first data lines disposed in a first area corresponding to the data driving circuit, and a plurality of second data lines disposed in a second area located outside of the first area, a timing controller configured to control the data driving circuit and the gate driving circuit, wherein the display panel includes a plurality of first data link lines for connecting the plurality of the first data lines to the data driving circuit, and a plurality of second data link lines with connecting paths of a stepped line structure for connecting the plurality of second data lines to the data driving circuit.

The plurality of first data lines are connected to the data driving circuit through the plurality of first data link lines in a straight line structure.

The plurality of second data link lines include a plurality of (2-1)th data link lines extending from the data driving circuit, a plurality of (2-2)th data link lines disposed in the display panel, and a plurality of (2-3)th data link lines for connecting the plurality of (2-2)th data link lines to the plurality of second data lines through the connecting paths of a stepped line structure.

The plurality of (2-1)th data link lines are disposed in a bezel area.

The plurality of (2-2)th data link lines are disposed in parallel to the plurality of first data lines.

The plurality of (2-2)th data link lines have the same lengths.

The plurality of (2-2)th data link lines are disposed in the same layer as the plurality of first data lines.

The plurality of (2-2)th data link lines are disposed in a different layer from the plurality of (2-3)th data link lines.

The connecting paths of the stepped line structure are formed through contact holes for connecting the plurality of (2-2)th data link lines and the plurality of (2-3)th data link lines.

The plurality of (2-3)th data link lines are located in a step area spaced apart from a reference distance or more from the data driving circuit.

The plurality of (2-3)th data link lines have step widths of more than a unit subpixel.

The plurality of (2-3)th data link lines have a central downward stepped line structure that goes downward toward a center of the display panel.

The plurality of (2-3)th data link lines have an outer downward stepped line structure that goes downward toward outer edges of the display panel.

The plurality of (2-2)th data link lines are disposed at a position spaced apart from a reference distance or more from the source electrode of a driving transistor disposed in a subpixel.

The plurality of (2-3)th data link lines are formed to be symmetrical with respect to a center of the display panel.

The plurality of (2-3)th data link lines disposed in a straight area have a straight line structure.

The plurality of (2-3)th data link lines have the same lengths.

A display panel according to embodiments of the present disclosure can include a plurality of subpixels, a plurality of first data lines disposed in a first area corresponding to a data driving circuit, a plurality of second data lines disposed in a second area located outside of the first area, a plurality of gate lines, a plurality of first data link lines for connecting the first data lines to the data driving circuit, and a plurality of second data link lines with connecting paths of stepped line structure for connecting the plurality of second data lines to the data driving circuit.

A display panel according to embodiments of the present disclosure can include a substrate, a first buffer layer disposed on the substrate, a driving transistor disposed on the first buffer layer, a first interlayer insulating film disposed on the driving transistor, a second buffer layer disposed on the first interlayer insulating film, at least one switching transistor disposed on the second buffer layer, a second interlayer insulating film formed to cover the at least one switching transistor, a plurality of (2-3)th data link lines disposed on the second interlayer insulating film, a first planarization layer formed to cover the plurality of (2-3)th data link lines, a plurality of data lines and a plurality of (2-2)th data link lines disposed on the first planarization layer, a second planarization layer formed to cover the plurality of data lines and the plurality of (2-2)th data link lines on the first planarization layer, and a light emitting element disposed on the second planarization layer, wherein the plurality of (2-2)th data link lines are connected to a plurality of (2-1)th data link lines extending from the data driving circuit, and wherein the plurality of data lines and the plurality of (2-2)th data link lines are connected to the plurality of (2-3)th data link lines through contact holes.

A plurality of first data lines disposed in a first area corresponding to the data driving circuit among the plurality of data lines are connected to the data driving circuit through a plurality of first data link lines, and a plurality of second data lines disposed in a second area located outside of the first area among the plurality of data lines are connected to the data driving circuit through the plurality of (2-1)th data link lines, the plurality of (2-2)th data link lines and the plurality of (2-3)th data link lines with connection paths of stepped line structure.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. For example, the disclosed embodiments of the present disclosure are intended to illustrate the scope of the technical idea of the present disclosure.

What is claimed is:

1. A display device comprising:
a data driving circuit configured to supply a plurality of data voltages to a plurality of data lines, wherein the plurality of data lines comprise a plurality of first data lines and a plurality of second data lines;
a gate driving circuit configured to supply a plurality of gate signals to a plurality of gate lines; and
a display panel having the plurality of first data lines disposed in a first area corresponding to the data driving circuit, and the plurality of second data lines disposed in a second area located outside of the first area,
wherein the display panel includes:
a plurality of first data link lines for connecting the plurality of the first data lines to the data driving circuit; and
a plurality of second data link lines with connecting paths arranged in a stepped line configuration, for connecting the plurality of second data lines to the data driving circuit.

2. The display device according to claim 1, wherein the plurality of first data lines are connected to the data driving circuit through the plurality of first data link lines in a straight line configuration.

3. The display device according to claim 1, wherein the plurality of second data link lines include:
a plurality of (2-1)th data link lines extending from the data driving circuit;
a plurality of (2-2)th data link lines disposed in the display panel; and
a plurality of (2-3)th data link lines, for connecting the plurality of (2-2)th data link lines to the second data lines through the connecting paths arranged in the stepped line configuration.

4. The display device according to claim 3, wherein the plurality of (2-1)th data link lines are disposed in a bezel area disposed outside of the display area of the display panel.

5. The display device according to claim 3, wherein the plurality of (2-2)th data link lines are disposed in parallel to the plurality of first data lines.

6. The display device according to claim 3, wherein the plurality of (2-2)th data link lines have same lengths.

7. The display device according to claim 3, wherein the plurality of (2-2)th data link lines are disposed in a same layer as the plurality of first data lines.

8. The display device according to claim 3, wherein the plurality of (2-2)th data link lines are disposed in a different layer from the plurality of (2-3)th data link lines.

9. The display device according to claim 3, wherein the connecting paths arranged in the stepped line configuration are formed through contact holes for connecting the plurality of (2-2)th data link lines and the plurality of (2-3)th data link lines.

10. The display device according to claim 3, wherein the plurality of (2-3)th data link lines are located in a step area, which is spaced apart from at least a reference distance from the data driving circuit.

11. The display device according to claim 3, wherein the plurality of (2-3)th data link lines have step widths larger than a unit subpixel.

12. The display device according to claim 3, wherein the plurality of (2-3)th data link lines have a central downward stepped line configuration that goes downward toward a center or middle of the display panel.

13. The display device according to claim 3, wherein the plurality of (2-3)th data link lines have an outer downward stepped line configuration that goes downward toward outer edges of the display panel.

14. The display device according to claim 3, wherein the plurality of (2-2)th data link lines are disposed at a position, which is spaced apart from at least a reference distance from the source electrode of a driving transistor disposed in a subpixel in the display panel.

15. The display device according to claim 3, wherein the plurality of (2-3)th data link lines are formed to be symmetrical with respect to a center or middle of the display panel.

16. The display device according to claim 3, wherein the plurality of (2-3)th data link lines disposed in a straight area have a straight line configuration.

17. The display device according to claim 3, wherein the plurality of (2-3)th data link lines have same lengths.

18. The display device according to claim 1, wherein some of the plurality of second data link lines are disposed in a display area of the display panel, which is different from a bezel area of the display panel.

19. A display panel comprising:
a plurality of subpixels configured to display an image;
a plurality of first data lines disposed in a first area corresponding to a data driving circuit;
a plurality of second data lines disposed in a second area located outside of the first area;
a plurality of first data link lines for connecting the plurality of first data lines to the data driving circuit; and
a plurality of second data link lines having connecting paths arranged in a stepped line configuration, for connecting the plurality of second data lines to the data driving circuit.

20. The display panel according to claim 19, wherein the plurality of second data link lines and the plurality of subpixels are disposed in a display area of the display panel.

21. The display panel according to claim 19, wherein all the plurality of first data link lines are disposed in a bezel area of the display panel, and all the plurality of first link lines extend in a straight line through the entire bezel area.

22. The display panel according to claim 19, wherein the plurality of second data link lines are disposed perpendicular to each other.

23. A display device comprising:
the display panel according to claim 19; and
the data driving circuit disposed at one side of the display panel.

24. A display panel comprising:
a substrate;
a first buffer layer disposed on the substrate;
a driving transistor disposed on the first buffer layer;
a first interlayer insulating film disposed on the driving transistor;
a second buffer layer disposed on the first interlayer insulating film;
at least one switching transistor disposed on the second buffer layer;
a second interlayer insulating film disposed to cover the at least one switching transistor;
a plurality of (2-3)th data link lines disposed on the second interlayer insulating film;
a first planarization layer formed to cover the plurality of (2-3)th data link lines;
a plurality of data lines and a plurality of (2-2)th data link lines disposed on the first planarization layer;
a second planarization layer disposed to cover the plurality of data lines and the plurality of (2-2)th data link lines on the first planarization layer; and
a light emitting element disposed on the second planarization layer,
wherein the plurality of (2-2)th data link lines are connected to a plurality of (2-1)th data link lines extending from a data driving circuit, and
wherein the plurality of data lines and the plurality of (2-2)th data link lines are connected to the plurality of (2-3)th data link lines through contact holes.

25. The display panel according to claim 24, wherein a plurality of first data lines disposed in a first area corresponding to the data driving circuit, among the plurality of data lines, are connected to the data driving circuit through a plurality of first data link lines, and
a plurality of second data lines disposed in a second area located outside of the first area, among the plurality of data lines, are connected to the data driving circuit through the plurality of (2-1)th data link lines, the plurality of (2-2)th data link lines and the plurality of (2-3)th data link lines having connection paths arranged in a stepped line configuration.
